(19) United States
(12) Patent Application Publication
(10) Pub. No.: US 2012/0329377 A1
(43) Pub. Date: Dec. 27, 2012

(54) FAN CONTROL SYSTEM, COMPUTER SYSTEM, AND METHOD FOR CONTROLLING FAN SPEED THEREOF

(76) Inventor: Pei-Yu WU, New Taipei City (TW)

(21) Appl. No.: 13/302,253

(22) Filed: Nov. 22, 2011

(30) Foreign Application Priority Data
Jun. 27, 2011 (TW) 100122467

(51) Int. Cl. H05K 5/02

(52) U.S. Cl. 454/184

(57) ABSTRACT

A fan control system, a computer system, and a method for controlling fan speed thereof are disclosed. The fan control system is used for an electronic component of the computer system. The fan control system comprises a fan which is used for cooling the electronic component. A temperature measurement module is used for measuring a temperature of the electronic component. A control module is electrically connected with the fan and the temperature measurement module and is used for controlling a speed of the fan according to the temperature of the electronic component. When the temperature exceeds a first setting temperature and the speed is lower than a maximum setting speed, the control module controls the fan to increase the speed. When the temperature is lower than a second setting temperature and the speed exceeds a minimum setting speed, the control module controls the fan to decrease the speed.

### BACKGROUND OF THE INVENTION

1. Field of the Invention

The present invention relates to a fan control system, computer system, and method for controlling fan speed thereof; and more particularly, the present invention relates to a fan control system, computer system, and method for controlling fan speed which can control the fan in a non-linear way according to the temperature and fan speed.

2. Description of the Related Art

As technology evolves, a modern computer system shows strong computing power yet greater power consumption, which could lead to heat dissipation problems. Traditionally, heat dissipating fans are used for cooling the computer system. However, the fans could cost a lot of power if they are constantly operating.

In order to solve the above problem, a linear fan control method is disclosed and shown in FIG. 1A, which illustrates a coordinate view of a first embodiment of a linear fan control method in the prior art.

In the first embodiment of the prior art, the fan speed corresponds directly to the temperature of the computer system. When the temperature exceeds a first temperature 95, the fan speed increases from a minimum speed 91 to a maximum speed 92. However, the computer system has the fan speed increased even though the temperature does not reach a second temperature 96, which is the upper limit of the computer system; therefore, the computer system could waste extra power. Meanwhile, when the temperature of the computer system drops, the fan speed decreases immediately and vice versa. The sudden rise and drop of the fan speed could cause the fan to make a lot of noises not pleasant to the user.

Therefore, another linear fan control method is disclosed and shown in FIG. 1B, which illustrates a coordinate view of a second embodiment of a linear fan control method in the prior art.

In the second embodiment of the prior art, the fan speed is adjusted according to the temperature, and the fan speed does not increase proportionally as the temperature rises. Please refer to a speed curve 98 and a temperature curve 99, when the computer system reaches an initial temperature 97, the fan starts from a minimum speed 93 to a maximum speed 94. Although it is possible to reduce the power consumption of the fan in the second embodiment, it is also necessary to specify a fan speed parameter for each temperature, for example, 256 different fan speed parameters for 256 different temperatures. Besides, since different components such as chip or memory have different temperature operating ranges, the developers have to specify different fan speed parameters for different components. As there are more components in the computer system, setting fan speed parameters could mean a heavy burden for the developers.

### SUMMARY OF THE INVENTION

It is an object of the present invention to provide a fan control system which can control a fan in a non-linear way according to the temperature and fan speed.

It is another object of the present invention to provide a computer system having the fan control system.

It is still another object of the present invention to provide a method for controlling fan speed.

In order to achieve the above object, an embodiment of the invention discloses a fan control system for an electronic component of a computer system. The fan control system comprises a fan, a temperature measurement module, and a control module. The fan cools the electronic component. The temperature measurement module measures the temperature of the electronic component. The control module is electrically connected with the fan and the temperature measurement module and controls a speed of the fan according to the temperature of the electronic component, when the temperature exceeds a first setting temperature and the speed is lower than a maximum setting speed, the control module controls the fan to increase the speed; when the temperature is lower than a second setting temperature and the speed exceeds a minimum setting speed, the control module controls the fan to decrease the speed.

An embodiment of the invention discloses a computer system comprising an electronic component and a fan control system. The fan control system comprises a fan, a temperature measurement module, and a control module. The fan cools the electronic component. The temperature measurement module measures the temperature of the electronic component. The control module is electrically connected with the fan and the temperature measurement module and is used for controlling a speed of the fan according to the temperature of the electronic component. When the temperature exceeds a first setting temperature and the speed is lower than a maximum setting speed, the control module controls the fan to increase the speed; when the temperature is lower than a second setting temperature and the speed exceeds a minimum setting speed, the control module controls the fan to decrease the speed.

An embodiment of the invention discloses a method for controlling a speed of a fan in a computer system. The method comprises the steps of: measuring a temperature of the electronic component; when the temperature exceeds a first setting temperature and the speed is lower than a maximum setting speed, increasing the speed; and when the temperature is lower than a second setting temperature and the speed exceeds a minimum setting speed, decreasing the speed.

### BRIEF DESCRIPTION OF THE DRAWINGS

FIG. 1A illustrates a coordinate view of a first embodiment of a linear fan control method in the prior art;

FIG. 1B illustrates a coordinate view of a second embodiment of a linear fan control method in the prior art;

FIG. 2 illustrates a system structural view of a computer system according to an embodiment of the invention;

FIG. 3A-3C illustrate flow charts of a method for controlling fan speed; and

FIG. 4 illustrates a speed-versus-temperature view of a nonlinear fan control method according to an embodiment of the invention.

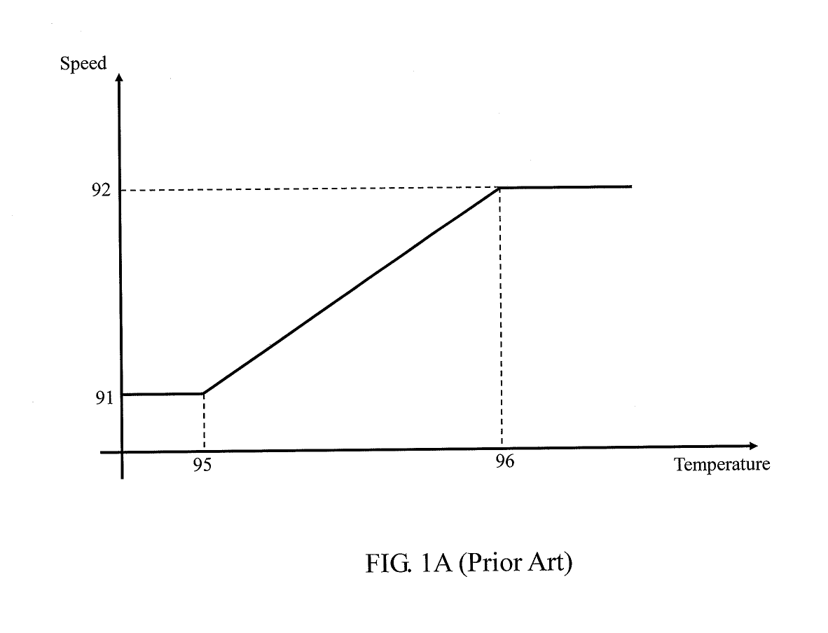

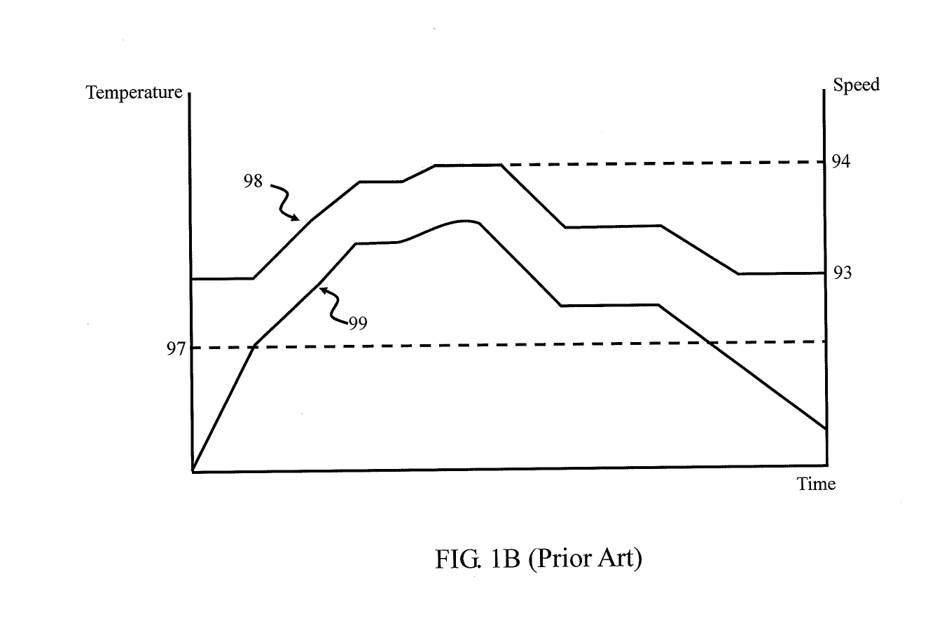

### DETAILED DESCRIPTION OF THE PREFERRED EMBODIMENT

The advantages and innovative features of the invention will become more apparent from the following detailed description when taken in conjunction with the accompanying drawings.

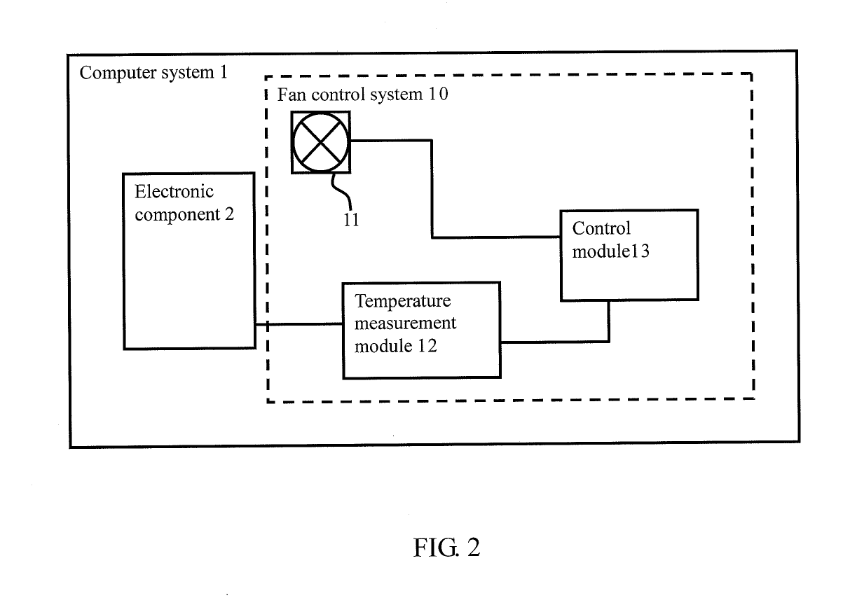

Please refer to FIG. 2 for a system structural view of a computer system according to an embodiment of the invention.

In an embodiment of the invention, a computer system 1 can be a desktop or notebook PC, or the like. The computer system 1 comprises an electronic component 2 and a fan control system 10. The electronic component 2 can be a central processing unit, memory module, or any circuit chip in the computer system 1. The electronic component 2 would generate heat due to its function or during its operation.

When the electronic component 2 generates heat, the fan control system 10 operates to cool the electronic component 2 to prevent the electronic component 2 from being damaged by high temperature. The fan control system 10 comprises a fan 11, a temperature measurement module 12, and a control module 13. The fan 11 provides an air flow to dissipate the heat generated by the electronic component 2. The temperature measurement module 12 can be implemented as a hardware structure or a hardware structure combining firmware to measure the temperature of the electronic component 2.

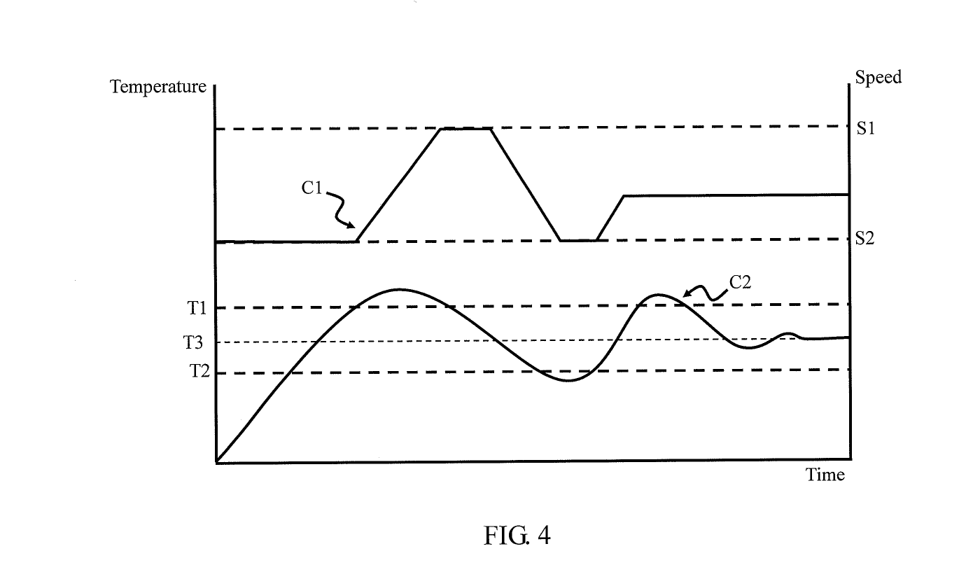

The control module 13 can be implemented as software, firmware or hardware, or the combination thereof. The control module 13 is electrically connected with the fan 11 or the temperature measurement module 12. Based on the temperature measured by the temperature measurement module 12, the control module 13 controls the speed of the fan 11 in a non-linear way to dissipate the heat generated by the electronic component 2. The control module 13 increases the speed of the fan 11 when the measured temperature exceeds a first setting temperature T1 (as shown in FIG. 4) and the speed of the fan 11 is lower than a maximum setting speed S1; the control module 13 decreases the speed of the fan 11 when the measured temperature is lower than a second setting temperature T2 and the speed of the fan 11 exceeds a minimum setting speed S2. Moreover, when the speed of the fan 11 reaches the maximum setting speed S1 and the temperature exceeds the maximum setting temperature, the control module 13 controls the computer system 1 to execute a shutdown process to protect the computer system 1. The control method of the control module 13 will be described later in details.

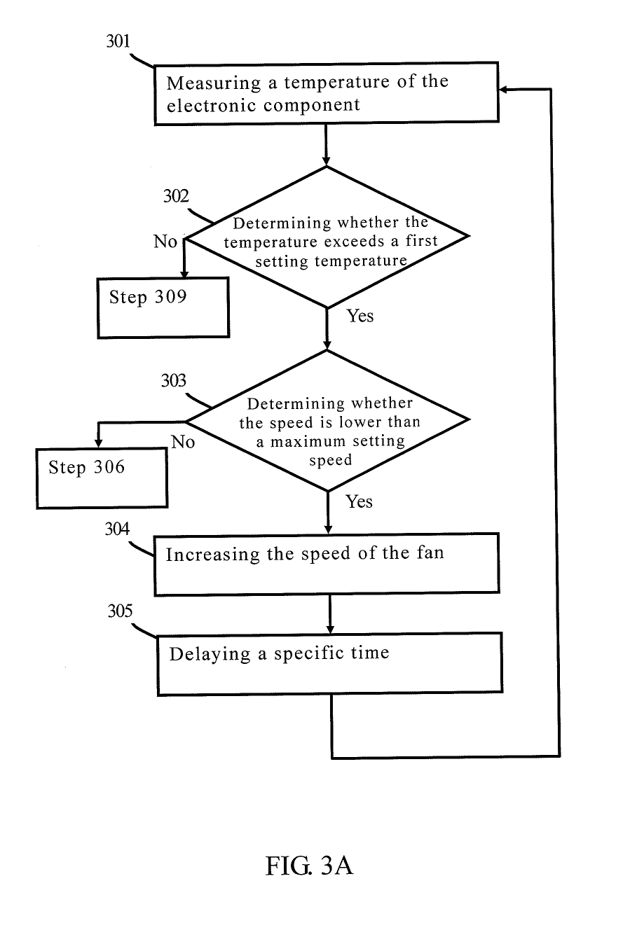

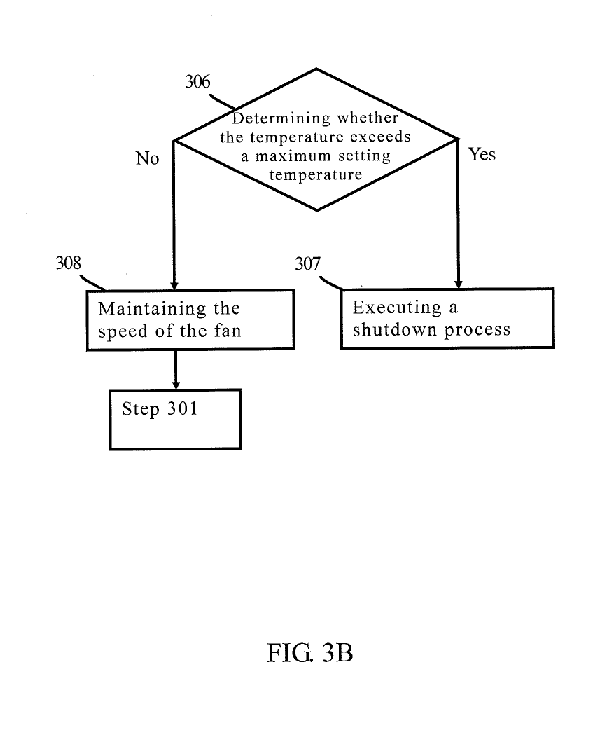

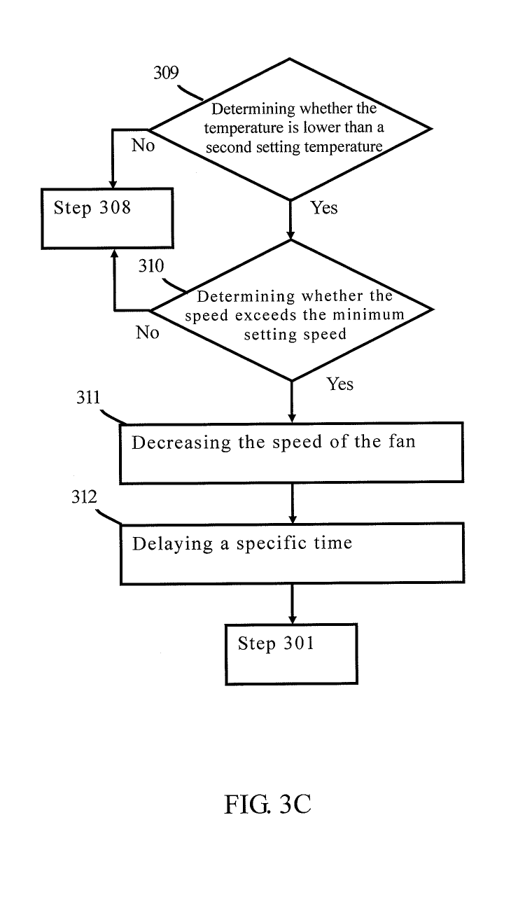

Please refer to FIG. 3A-3C for flow charts of a method for controlling fan speed. It is noted that the method is illustrated with the fan control system 10 of the computer system 1 in this description; however, the method can be applied in system other than the fan control system 10.

Please also refer to FIG. 4 for a speed-versus-temperature view of a nonlinear fan control method according to an embodiment of the invention. A speed curve C1 and a temperature curve are illustrated in FIG. 4.

First the method goes to step 301: measuring a temperature of the electronic component.

When the electronic component 2 of the computer system 1 is operating, the temperature measurement module 12 measures the temperature of the electronic component 2 first and then transmits the temperature data to the control module 13.

Then the method goes to step 302: determining whether the temperature exceeds a first setting temperature.

Then the control module 13 determines whether the temperature exceeds the first setting temperature T1, wherein the first setting temperature T1 is the maximum permissible temperature of the electronic component 2, such as 65° C. Each electronic component 2 has a different maximum permissible temperature, for example, the maximum permissible temperature of a memory module is 80° C., and that of the central processing unit (CPU) can be 100° C. Therefore, the first setting temperature T1 is set based on each electronic component 2.

When the temperature exceeds the first setting temperature T1, the method goes to step 303: determining whether the speed is lower than a maximum setting speed.

At this stage the control module 13 determines whether the speed of the fan 11 is lower than a maximum setting speed S1.

When the speed of the fan 11 is lower than the maximum setting speed S1, it is still possible for the fan 11 to increase its speed to enhance the heat dissipating effect, so the method goes to step 304: increasing the speed of the fan.

Therefore, at this time the control module 13 gradually increases the speed of the fan 11 according to an increasing rate to prevent the fan from making a lot of noises due to a sudden rise of the speed. In an embodiment of the present invention, the increasing rate can be 5% of the speed per unit time, or can be any other rate.

Then the method goes to step 305: delaying a specific time.

After the control module 13 delays a specific time, such as one second, the method goes back to step 301 to start the steps of controlling the speed of the fan 11 over again. In step 305, the operating stability of the fan can be greatly enhanced to prevent the fan 11 from making a lot of noises.

When the speed of the fan 11 is equal to or greater than the maximum setting speed S1, the method goes to step 306: determining whether the temperature exceeds a maximum setting temperature.

In this step, the control module 13 determines whether the temperature of the electronic component 2 exceeds the maximum setting temperature.

The maximum setting temperature can be set to be close or equal to the maximum permissible temperature of the electronic component 2, such as 70° C. If the current temperature exceeds the maximum setting temperature, the electronic component 2 could be damaged. In this case, the method goes to step 307: executing a shutdown process.

In step 307, the control module 13 forcibly shuts down the computer system 1 to protect the electronic component 2.

If the temperature does not exceed the maximum setting temperature, that is, the fan 11 is dissipating heat of the electronic component 2; therefore, the method goes to step 308: maintaining the speed of the fan.

Since the speed of the fan 11 has reached the maximum setting speed Si and the temperature of the electronic component 2 does not exceed the maximum setting temperature, that is, the electronic component 2 would not be damaged; the speed of the fan 11 is maintained to keep dissipating heat of the electronic component 2. Then goes back to step 301 to start the steps of controlling the speed of the fan 11 over again.

When the temperature of the electronic component 2 does not exceed the first setting temperature T1, the method goes to step 309: determining whether the temperature is lower than a second setting temperature.

The control module 13 determines whether the temperature of the electronic component 2 is lower than a second setting temperature T2. The second setting temperature T2 could be 5 to 10° C. lower than the first setting temperature T1, such as 60° C., or any temperature lower than the first setting temperature T1.

If the temperature of the electronic component 2 is between the first setting temperature T1 and the second setting temperature T2, that is, the temperature of the electronic component 2 remains stable; therefore, the control module 13 can execute step 308 to maintain the speed of the fan 11 and to let the fan 11 keep its speed.

If the electronic component 2 is lower than the second setting temperature T2, the control module 13 execute step 310: determining whether the speed exceeds the minimum setting speed.

Then the control module 13 determines whether the speed of the fan 11 exceeds the minimum setting speed S2. If the temperature of the electronic component 2 remains stable and would not damage the electronic component 2, and the speed of the fan 11 is lower or equal to the minimum setting speed S2, then the method goes to step 308 to maintain the speed of the fan 11 and to let the fan 11 keep its speed in order to reduce power consumption.

If the temperature of the electronic component 2 is lower than the second setting temperature T2 and the speed of the fan 11 still exceeds the minimum setting speed S2, the method goes to step 311: decreasing the speed of the fan.

Since the temperature of the electronic component 2 is lower than the second setting temperature T2 and in the safe range, the control module 13 gradually decreases the speed of the fan 11 according to a decreasing rate to prevent the speed of the fan 11 from dropping too fast and becoming unstable. In an embodiment of the present invention, the decreasing rate can be 5% of the speed per unit time, or can be any other rate.

Then the method goes to step 312: delaying a specific time.

Similarly, the control module 13 delays a specific time to go back to step 301 to start the steps of controlling the speed of the fan 11 over again and to enhance the operating stability of the fan 11.

It is noted that the method for controlling fan speed in the present invention does not need to follow the order of the step described above; the method can execute the steps in a different order as long as it fulfills the purpose of the present invention.

By controlling the fan in a non-linear way, the fan control system 10 can control the temperature curve C2 of the electronic component 2 to stay at the final temperature T3. Meanwhile, the programmer only needs to define a few parameters, such as the first setting temperature T1, the second setting temperature T2, the specific time for delay, the maximum setting temperature, the increasing rate, and the decreasing rate, thereby greatly reducing the design burden during fan setup.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A fan control system for an electronic component of a computer system, the fan control system comprising:
a fan for cooling the electronic component;
a temperature measurement module for measuring a temperature of the electronic component; and
a control module electrically connected with the fan and the temperature measurement module and used for controlling a speed of the fan according to the temperature of the electronic component, when the temperature exceeds a first setting temperature and the speed is lower than a maximum setting speed, the control module controls the fan to increase the speed; when the temperature is lower than a second setting temperature and the speed exceeds a minimum setting speed, the control module controls the fan to decrease the speed.

2. The fan control system as claimed in claim 1, wherein when the speed exceeds or is equal to the maximum setting speed and the temperature exceeds a maximum setting temperature, the control module controls the computer system to execute a shutdown process.

3. The fan control system as claimed in claim 1, wherein when the temperature is lower than the first setting temperature and the temperature exceeds the second setting temperature, the control module maintains the speed of the fan.

4. The fan control system as claimed in claim 1, wherein the control module controls the fan to increase the speed according to an increasing rate.

5. The fan control system as claimed in claim 4, wherein the control module further delays a specific time and then controls the fan again.

6. The fan control system as claimed in claim 1, wherein the control module controls the fan to decrease the speed according to a decreasing rate.

7. A computer system, comprising:
an electronic component; and
a fan control system for the electronic component, the fan control system comprising:
a fan for cooling the electronic component;
a temperature measurement module for measuring a temperature of the electronic component; and
a control module electrically connected with the fan and the temperature measurement module and used for controlling a speed of the fan according to the temperature of the electronic component, when the temperature exceeds a first setting temperature and the speed is lower than a maximum setting speed, the control module controls the fan to increase the speed; when the temperature is lower than a second setting temperature and the speed exceeds a minimum setting speed, the control module controls the fan to decrease the speed.

8. The computer system as claimed in claim 7, wherein when the speed exceeds or is equal to the maximum setting speed and the temperature exceeds a maximum setting temperature; the control module controls the computer system to execute a shutdown process.

9. The computer system as claimed in claim 7, wherein when the temperature is lower than the first setting temperature and exceeds the second setting temperature, the control module maintains the speed of the fan.

10. The computer system as claimed in claim 7, wherein the control module controls the fan to increase the speed according to an increasing rate.

11. The computer system as claimed in claim 10, wherein the control module further delays a specific time and then controls the fan again.

12. The computer system as claimed in claim 7, wherein the control module controls the fan to decrease the speed according to a decreasing rate.

13. A method for controlling a speed of a fan in a computer system, the method comprising the steps of:
measuring a temperature of the electronic component;
when the temperature exceeds a first setting temperature and the speed is lower than a maximum setting speed, increasing the speed; and
when the temperature is lower than a second setting temperature and the speed exceeds a minimum setting speed, decreasing the speed.

14. The method for controlling a speed of a fan in a computer system as claimed in claim 13, further comprising the step of:
when the speed exceeds or is equal to the maximum setting speed and the temperature exceeds a maximum setting temperature, executing a shutdown process.

15. The method for controlling a speed of a fan in a computer system as claimed in claim 13, further comprising the step of:
when the temperature is lower than the first temperature and exceeds the second setting temperature, maintaining the speed of the fan.

16. The method for controlling a speed of a fan in a computer system as claimed in claim 13, further comprising the step of:
increasing the speed according to an increasing rate.

17. The method for controlling a speed of a fan in a computer system as claimed in claim 16, further comprising the steps of:
delaying a specific time after increasing the speed of the fan; and
measuring the temperature of the electronic component again.

18. The method for controlling a speed of a fan in a computer system as claimed in claim 13, further comprising the step of:
decreasing the speed according to a decreasing rate.

19. The method for controlling a speed of a fan in a computer system as claimed in claim 18, further comprising the step of:
delaying a specific time after decreasing the speed of the fan; and
measuring the temperature of the electronic component again.
